(19) United States
(12) Patent Application Publication
(10) Pub. No.: US 2025/0041911 A1
(43) Pub. Date: Feb. 6, 2025

(54) OZONE WATER SUPPLYING UNIT AND SUBSTRATE TREATING APPARATUS INCLUDING THE SAME

(71) Applicant: SEMES CO., LTD., Cheonan-si (KR)

(72) Inventors: Myung A JEON, Yeosu-si (KR); Yong Hoon HONG, Seoul (KR); Ji Su HONG, Asan-si (KR); Bok Kyu LEE, Cheonan-si (KR); Young Seop CHOI, Cheonan-si (KR)

(73) Assignee: SEMES CO., LTD., Cheonan-si (KR)

(21) Appl. No.: 18/791,839

(22) Filed: Aug. 1, 2024

(30) Foreign Application Priority Data
Aug. 2, 2023 (KR) 10-2023-0101237

(51) Int. Cl. B08B 3/10; B08B 3/02; B08B 13/00

(52) U.S. Cl. CPC B08B 3/10; B08B 3/02; B08B 13/00; B08B 2203/005

(57) ABSTRACT

Disclosed is an ozone water supplying unit capable of maintaining a stable ozone concentration of ozone water supplied to a substrate, and a substrate treating apparatus including the same. The substrate treating apparatus includes: a chamber for liquid-treating a substrate loaded into a treating space with a liquid containing ozone water; and an ozone water supplying unit for supplying ozone water to the treating space, in which the ozone water supplying unit includes: an ozone water generator for generating ozone water; an ozone water supply line for supplying ozone water generated by the ozone water generator to the treating space; and a cooler provided in the ozone water supply line to cool the ozone water flowing through the ozone water supply line.

### CROSS-REFERENCE TO RELATED APPLICATIONS

This application claims priority to and the benefit of Korean Patent Application No. 10-2023-0101237 filed in the Korean Intellectual Property Office on Aug. 2, 2023, the entire contents of which are incorporated herein by reference.

### TECHNICAL FIELD

The present invention relates to an apparatus and a method for liquid-treating a substrate, and more particularly to an apparatus for treating a substrate by using ozone water, and to an ozone water supplying unit for supplying ozone water for use therein.

### BACKGROUND ART

In order to manufacture a semiconductor device or a liquid crystal display, various processes, such as photography, ashing, ion implantation, thin film deposition, and cleaning, are performed on a substrate. The cleaning process consists of a chemical treatment operation, a rinse operation, and a drying operation which are sequentially performed. In the chemical treatment operation, chemicals are supplied to the substrate to etch a thin film formed on a substrate or remove foreign substances on the substrate, and in the rinse treatment operation, a rinse liquid, such as pure water, is supplied to the substrate.

On the other hand, a treatment solution containing ozone water is used as a treatment solution used during the process to clean the organic matter. Ozone water is mixed with pure water or Hydrogen Fluoride, filtered by a filter, and used. Ozone water is highly reactive and unstable, so it is difficult to supply the ozone water to the substrate while maintaining the concentration of ozone water at the set concentration. In addition, when ozone water passes through the filter, it is easy to generate bubbles due to pressure changes, and the ozone in the ozone water is easy to decompose.

### SUMMARY OF THE INVENTION

The present invention has been made in an effort to provide an ozone water supplying unit for efficiently treating a substrate, and a substrate treating apparatus including the same.

The present invention has also been made in an effort to provide an ozone water supplying unit capable of improving the ability to clean a substrate by ozone water, and a substrate treating apparatus including the same.

The present invention has also been made in an effort to provide an ozone water supplying unit capable of maintaining a stable ozone concentration of ozone water supplied to a substrate, and a substrate treating apparatus including the same.

The present invention has also been made in an effort to provide an ozone water supplying unit capable of preventing the ozone concentration in the ozone water from decreasing when the ozone water passes through a filter, and a substrate treating apparatus including the same.

The present invention is not limited thereto, and other objects not mentioned will be clearly understood by those of ordinary skill in the art from the following description.

An exemplary embodiment of the present invention provides a substrate treating apparatus includes: a chamber for liquid-treating a substrate loaded into a treating space with a liquid containing ozone water; and an ozone water supplying unit for supplying ozone water to the treating space, in which the ozone water supplying unit includes: an ozone water generator for generating ozone water; an ozone water supply line for supplying ozone water generated by the ozone water generator to the treating space; and a cooler provided in the ozone water supply line to cool the ozone water flowing through the ozone water supply line.

According to the exemplary embodiment, the cooler may adjust a temperature of the ozone water to a temperature lower than room temperature.

According to the exemplary embodiment, the ozone water supplying unit may further include a filter installed in the ozone water supply line, and the filter may be installed downstream of the cooler.

According to the exemplary embodiment, the filter may be located adjacent to the cooler.

According to the exemplary embodiment, the ozone water supplying unit may further include a heat reserving member for maintaining a temperature of the ozone water supply line to be constant, and the heat reserving member may be provided to be wrapped around the ozone water supply line downstream of the cooler.

According to the exemplary embodiment, the substrate treating apparatus may further include: a treatment solution supply source for storing a treatment solution; a treatment solution supply line for supplying a treatment solution from the treatment solution supply source to the ozone water supply line; and a mixer installed in the ozone water supply line to mix the ozone water with the treatment solution.

According to the exemplary embodiment, the mixer may be provided upstream of the cooler.

According to the exemplary embodiment, the mixer may include an inline mixer.

According to the exemplary embodiment, the treatment solution may be deionized water.

According to the exemplary embodiment, the treatment solution may be a chemical solution.

According to the exemplary embodiment, the chemical solution may be hydrogen fluoride.

According to the exemplary embodiment, the chamber may include: a housing providing an inner space; a cup for providing the treating space; a support unit for supporting the substrate; a nozzle for supplying ozone water to the substrate, and the ozone water supply line may be connected to the nozzle.

Another exemplary embodiment of the present invention provides a unit for supplying a treatment solution, the unit including: a treatment solution supply source for providing a treatment solution; a treatment solution supply line for supplying a treatment solution from said treatment solution supply source; a cooler for cooling said treatment solution; and a filter, in which the cooler and the filter may be disposed in said treatment solution supply line.

According to the exemplary embodiment, the filter may be located adjacent to the chiller, but may be located downstream of the cooler.

According to the exemplary embodiment, the cooler may cool the ozone water to a temperature lower than room temperature.

According to the exemplary embodiment, the ozone water supplying unit may further include a heat reserving member, and the heat reserving member may be provided to be wrapped around the ozone water supply line downstream of the cooler.

According to the exemplary embodiment, the treatment solution may include ozone water.

Still another exemplary embodiment of the present invention provides an apparatus for treating a substrate, the apparatus including: a chamber for liquid-treating a substrate loaded into a treating space with a treatment solution; and an ozone water supplying unit for supplying a liquid containing ozone water to the treating space, in which the ozone water supplying unit may include: an ozone water generator for generating ozone water; a first ozone water supply line for connecting the ozone water generator with a first nozzle supplying the ozone water to the treating space; a first cooler provided in the first ozone water supply line to cool the ozone water flowing through the first ozone water supply line; a first heat reserving member provided to be wrapped around the first ozone water supply line downstream of the first cooler to maintain a temperature of the first ozone water supply line; a pure water supply line for supplying pure water to the first ozone water supply line; a pure water supply source for supplying the pure water to the pure water supply line; a first mixer provided in the first ozone water supply line and located upstream of the first cooler, and mixing the pure water with the ozone water; a second ozone water supply line connecting the ozone water generator with a second nozzle supplying the ozone water to the treating space; a second cooler provided in the second ozone water supply line to cool the ozone water flowing through the second ozone water supply line; a second heat reserving member provided to be wrapped around the second ozone water supply line downstream of the second cooler to maintain a temperature of the second ozone water supply line; a chemical solution supply line for providing a chemical solution to the second ozone water supply line; a chemical solution supply source for providing the chemical solution to the chemical solution supply line; and a second mixer provided in the second ozone water supply line and located upstream of the second cooler, and mixing the chemical solution with the ozone water.

According to the exemplary embodiment, the substrate treating apparatus may further include: a first filter disposed adjacent to the first cooler downstream of the first cooler; and a second filter disposed adjacent to the second cooler downstream of the first cooler.

According to the exemplary embodiment, the first treatment solution may be a chemical solution containing ozone water, and the second treatment solution may be a chemical solution containing hydrogen fluoride.

According to the exemplary embodiment of the present invention, it is possible to efficiently treat the substrate.

Further, according to the exemplary embodiment of the present invention, it is possible to improve the ability of the treatment solution to clean the substrate.

Further, according to the exemplary embodiment of the present invention, it is possible to improve the substrate cleaning performance by ozone water.

Further, according to the exemplary embodiment of the present invention, it is possible to stably maintain the ozone concentration of the ozone water supplied to the substrate.

Further, according to the exemplary embodiment of the present invention, it is possible to use a filter with improved filtration.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate treating apparatus according to an exemplary embodiment of the present invention.

FIG. 2 is a diagram schematically illustrating a liquid treating chamber according to an exemplary embodiment of the present invention.

FIG. 3 is a diagram schematically illustrating an ozone water supplying unit according to an exemplary embodiment of the present invention.

FIG. 4 is a diagram schematically illustrating an ozone water supplying unit according to another exemplary embodiment of the present invention.

FIG. 5 is a diagram schematically illustrating an ozone water supplying unit according to still another exemplary embodiment of the present invention.

FIG. 6 is a diagram schematically illustrating an ozone water supplying unit according to still yet another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, an exemplary embodiment of the present invention will be described with reference to the accompanying drawings.

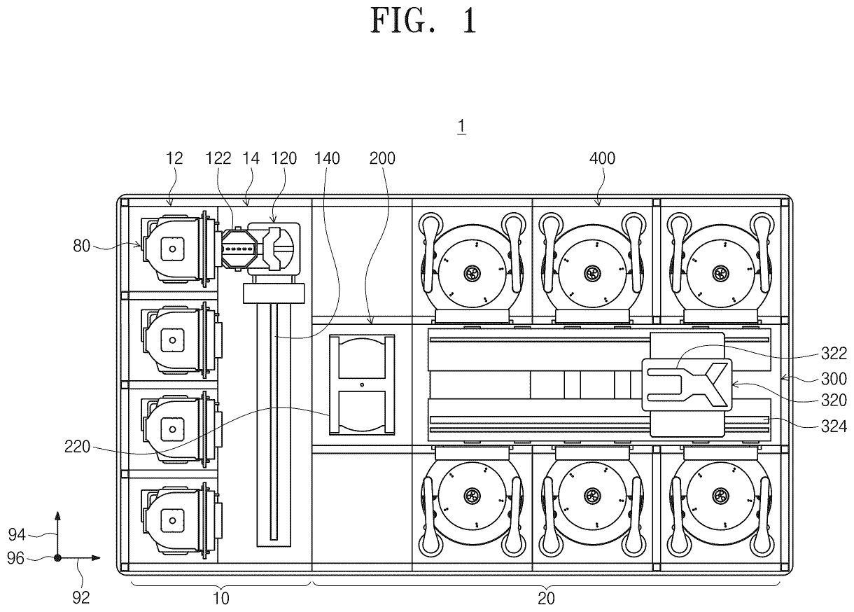

FIG. 1 is a top plan view schematically illustrating a substrate W treating apparatus according to an exemplary embodiment of the present invention. Referring to FIG. 1, the substrate W treating apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transport means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 is provided to be spaced apart in the vertical direction, and the hands 122 may move forward and backward independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forward and backward, rotatable about the third direction 96, and movable along the third direction 96. A plurality of hands 322 is provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

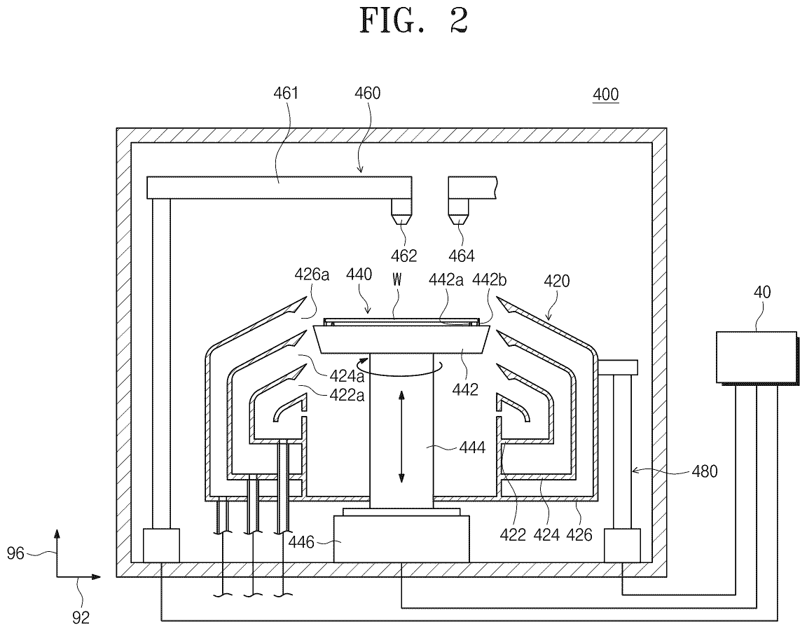

FIG. 2 is a diagram schematically illustrating the liquid treating chamber 400 according to the exemplary embodiment of the present invention. Referring to FIG. 2, the liquid treating chamber 400 has a housing 410, a cup 420, a support unit 440, a nozzle unit 460, a lifting unit 480, an ozone water supplying unit 1000, and a controller.

The housing 410 is provided in a generally rectangular parallelepiped shape. The cup 420, the support unit 440, and the liquid supplying unit 460 are disposed in the housing 410.

The cup 420 has a treating space with an open top, and the substrate W is liquid-treated in the treating space. The support unit 440 supports the substrate W in the treating space. The liquid supplying unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to the example, the cup 420 includes a plurality of collection containers 422, 424, and 426. The collection containers 422, 424, and 426 each have a collection space for collecting the liquid used to treat the substrate W. Each of the collection containers 422, 424, and 426 is provided in a ring shape surrounding the support unit 440. When the liquid treatment process is in progress, the treatment solution scattered by the rotation of the substrate W is introduced into the collection space through inlets 422a, 424a, and 426a of the respective collection containers 422, 424, and 426. According to the example, the cup 420 includes a first collection container 422, a second collection container 424, and a third collection container 426. The first collection container 422 is disposed to surround the support unit 440, the second collection container 424 is disposed to surround the first collection container 422, and the third collection container 426 is disposed to surround the second collection container 424. A second inlet 424a, which introduces the liquid into the second collection container 424, may be located above a first inlet 422a, which introduces the liquid into the first collection container 422, and a third inlet 426a, which introduces the liquid into the third collection container 426, may be located above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The driving shaft 444 is driven by a driver 446, is connected to the center of the bottom surface of the substrate W, and rotates the support plate 442 with respect to the central axis thereof.

The nozzle unit 460 includes a first nozzle 462 and a second nozzle 464. The first nozzle 462 supplies a first treatment solution onto the substrate W. The first treatment solution may be a solution having a temperature below room temperature. In one example, the first treatment solution may be ozone water. The ozone water may be a solution of ozone (O₃) gas dissolved in water. The water may be pure water or deionized water. The second nozzle 464 supplies a second treatment solution onto the substrate W. The second treatment solution may be Hydrogen Fluorine (HF). Optionally, the second treatment solution may be a mixture of ozone water and hydrogen fluoride. The first nozzle 462 and the second nozzle 464 are respectively supported on different arms 461, and the arms 461 may be moved independently. Optionally, the first nozzle 462 and the second nozzle 464 may be mounted on the same arm and moved at the same time.

Optionally, the liquid supplying unit may further include one or more nozzles in addition to the first nozzle 462 and the second nozzle 464. Additional nozzles may be added to supply different types of treatment solution to the substrate W. For example, another kind of treatment solution may be an acid solution or a base solution for removing foreign substances from the substrate W. In addition, another type of treatment solution may be alcohol having surface tension lower than that of water. For example, the alcohol may be isopropyl alcohol.

The lifting unit 480 moves the cup 420 in the vertical direction. By the vertical movement of the cup 420, a relative height between the cup 420 and the substrate W is changed. Accordingly, since the collection containers 422, 424, and 426 for collecting the treatment solution are changed according to the type of the liquid supplied to the substrate W, the liquids may be separated and collected. Unlike the above, the cup 420 may be fixedly installed, and the lifting unit 480 may move the support unit 440 in the vertical direction.

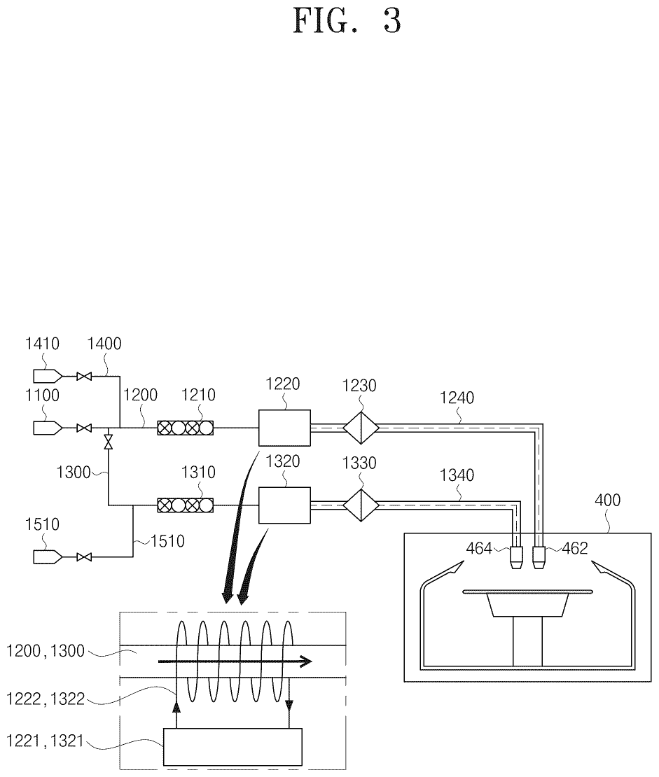

FIG. 3 is a diagram schematically illustrating an ozone water supplying unit according to an exemplary embodiment of the present invention.

The ozone water supplying unit 1000 includes an ozone water generator 1100, a first ozone water supply line 1200, a second ozone water supply line 1300, and a controller. The ozone water generator 1100 supplies ozone water to the first ozone water supply line 1200 and the second ozone water supply line 1300. In the first ozone water supply line 1200, a first mixer 1210, a first cooler 1220, a first filter 1230, and a first heat preservation element 1240 are installed. A pure water supply line 1400 is connected to the first ozone water supply line 1200. In the second ozone water supply line 1300, a second mixer 1310, a second cooler 1320, a second filter 1330, and a second heat preservation element 1340 are installed. A chemical solution supply line 1500 is connected to the second ozone water supply line 1300. The ozone water supplying unit 1000 supplies a treatment solution into the liquid treating chamber 400. The treatment solution may be a solution containing ozone water. The amount of dissolved ozone in the ozone water contained in the treatment solution is provided as a preset value. For example, the amount of dissolved ozone may be provided as 30 ppm or 80 ppm. Alternatively, the amount of dissolved ozone may be provided as 80 ppm or more. The amount of dissolved ozone in the treatment solution may vary depending on the type of film formed on the substrate W.

The ozone water generator 1100 produces ozone water. In one example, the ozone water generator 1100 may be an ozone water generator that dissolves ozone gas in water. The ozone water generator may dissolve ozone gas in water at high pressure. Alternatively, the ozone water generator may dissolve ozone gas in water by using electrical energy. The water may be pure water or deionized water. The ozone water generator produces and delivers ozone water at a set concentration. The amount of dissolved ozone in the ozone water may vary depending on the type of process and the type of film formed on the substrate W.

One end of the first ozone water supply line 1200 is connected to the ozone water generator 1100 and the other end of the first ozone water supply line 1200 is connected to the first nozzle 462 in the plurality of liquid treating chambers 400. In addition, the pure water supply line 1400 is connected to the first ozone water supply line 1200. The first ozone water supply line 1200 supplies ozone water from the ozone water generator 1100 to the plurality of liquid treating chambers 400. The first ozone water supply line 1100 may also supply a mixed solution of pure water and ozone water to the plurality of liquid treating chambers 400. The first nozzle 462 supplies ozone water or the mixed solution to the substrate W. The first ozone water supply line 1200 and the pure water supply line 1400 may be provided with a flowmeter (or liquid flow controller) 1260 and/or valves. The first ozone water supply line 1200 may be provided with a first mixer 1210, a first cooler 1220, a first filter 1230, and a first heat retaining element 1240. The first mixer 1210, the first cooler 1220, the first filter 1230, and the first heat retaining element 1240, the flowmeter 1260, and the valves may be controlled by a controller.

The pure water supply line 1400 connects a pure water supply source 1410 to the first ozone water supply line 1200. The pure water supply line 1400 may be connected to the first ozone water supply line 1200 upstream of the first mixer 1310. The pure water supply line 1400 supplies pure water to the first ozone water supply line 1200.

The first mixer 1210 is installed on the first ozone water supply line 1200. The first mixer 1210 may be located upstream of the first cooler 1220 and the first filter 1230. The first mixer 1210 may be located downstream of the point where the pure water supply line 1400 is connected with the first ozone water supply line 1200. The first mixer 1210 mixes the ozone water and pure water. The first mixer 1210 may be an inline mixer.

The first cooler 1220 is installed in the first ozone water supply line 1200. The first cooler 1220 may be located downstream of the first mixer 1210, which will be described later, on the first ozone water supply line 1200. The first cooler 1220 cools the treatment solution. The first cooler 1220 cools the treatment solution to a temperature below room temperature. In one example, the first cooler 1220 cools the treatment solution to a temperature between 4° C. to 20° C. For example, the first cooler 1130 may cool the treatment solution to 15° C. The first cooler 1220 is provided with a chiller 1221 and a pipe 1222. Ozone water flowing through the first ozone water supply line 1200 may be cooled by heat exchange between the pipe 1222 through which cooling water flows and the first ozone water supply line 1200 through which ozone water flows.

The first filter 1230 is installed on the first ozone water supply line 1200. The first filter 1230 may be located downstream of the first cooler 1220. The first filter 1230 filters foreign substances in the ozone water. The foreign substance is filtered through pores in the second filter 1330. The smaller the size of the pore is, the greater the filtration capacity of the second filter 1330 is. As the temperature of the ozone water is low, the pore size may be further decreased.

The first heat reserving member 1240 is provided on the first ozone water supply line 1200. The first heat reserving member 1240 may be provided in the first ozone water supply line 1200 downstream of the first cooler 1220. When the first filter 1230 is installed downstream of the first cooler 1220, the first heat reserving member 1240 may be provided between the first filter 1230 and the first cooler 1220, and between the first filter 1230 and the first nozzle 462. The first heat reserving member 1240 may be provided to be wrapped around the first ozone water supply line 1200. The first heat reserving member 1240 may be wrapped around the treatment solution supply line 1100 in a unidirectionally wrapping manner. The first heat reserving member 1240 may be provided from a polyvinyl chloride or Styrofoam material. The first heat reserving member 1240 blocks the first ozone water supply line 1200 from contact with the outside. The first heat reserving member 1240 blocks heat exchange between the treatment solution supply line 1100 and the outside. The first heat reserving member 1240 maintains the first ozone water supply line 1200 at a constant temperature.

One end of the second ozone water supply line 1300 is connected to the ozone water generator 1100 and the other end of the second ozone water supply line 1300 is connected to the second nozzle 464 in the plurality of liquid treating chambers 400. In addition, the chemical solution supply line 1500 is connected to the second ozone water supply line 1300. The second ozone water supply line 1300 supplies ozone water from the ozone water generator 1100 to the plurality of liquid treating chambers 400. The second ozone water supply line 1300 may also supply a mixed solution of the chemical solution and ozone water to the plurality of liquid treating chambers 400. The second nozzle 464 supplies the ozone water or the mixed solution to the substrate W. The second ozone water supply line 1300 and the chemical solution water supply line 1400 may be provided with a flowmeter (or liquid flow controller) 1360 and/or valves. The second ozone water supply line 1300 may be provided with a second mixer 1310, a second cooler 1320, a second filter 1330, and a second heat reserving member 1340. The second mixer 1310, the second cooler 1320, the second filter 1330, and the second heat reserving member 1340, the flow meter 1360, and the valves may be controlled by a controller.

The chemical solution supply line 1500 connects the chemical solution supply source 1510 and the second ozone water supply line 1300. The chemical solution supply line 1500 may be connected to the second ozone water supply line 1300 upstream of the second mixer 1310. The chemical solution supply line 1500 supplies a chemical solution to the second ozone water supply line 1300. In one example, the chemical solution may be hydrogen fluoride (HF).

The second mixer 1310 is installed on the second ozone water supply line 1300. The second mixer 1310 may be located upstream of the second cooler 1320 and the second filter 1330. The second mixer 1310 may be located downstream of the point where the chemical solution supply line 1500 is connected with the second ozone water supply line 1300. The second mixer 1310 mixes the ozone water and the chemical solution. The second mixer 1310 may be an inline mixer.

The second cooler 1320 is installed in the second ozone water supply line 1300. The second cooler 1320 may be located downstream of the second mixer 1310, which will be described later, on the second ozone water supply line 1300. The second cooler 1320 cools the treatment solution. The second cooler 1320 cools the treatment solution to a temperature below room temperature. In one example, the second cooler 1320 cools the treatment solution to a temperature between 4° C. and 20° C. For example, the second cooler 1130 may cool the treatment solution to 15° C. The second cooler 1320 is provided with a chiller 1321 and a pipe 1322. The ozone water flowing through the second ozone water supply line 1300 may be cooled by heat exchange between the pipe 1322 through which the cooling water flows and the second ozone water supply line 1300 through which ozone water flows.

The second filter 1330 is installed on the second ozone water supply line 1300. The second filter 1330 may be located downstream of the second cooler 1320. The second filter 1330 filters foreign substances in the ozone water. The second filter 1330 includes pores. The foreign substance is filtered through pores in the second filter 1330. The smaller the size of the pore is, the greater the filtration capacity of the second filter 1330 is. As the temperature of the ozone water is low, the pore size may be further decreased.

The second heat reserving member 1340 is provided on the second ozone water supply line 1300. The second heat reserving member 1340 may be provided in the second ozone water supply line 1300 downstream of the second cooler 1320. When the second filter 1330 is installed downstream of the second cooler 1320, the second heat reserving member 1340 may be provided between the second filter 1330 and the second cooler 1320, and between the second filter 1330 and the second nozzle 464. The second heat reserving member 1340 may be provided to be wrapped around the second ozone water supply line 1300. The second heat reserving member 1340 may be wrapped around the treatment fluid supply line 1100 in a unidirectionally wrapping manner. The second heat reserving member 1340 may be provided from a polyvinyl chloride or Styrofoam material. The second heat reserving member 1340 blocks a contact between the second ozone water supply line 1300 and the outside. The second heat reserving member 1340 blocks heat exchange between the treatment solution supply line 1100 and the outside. The second heat reserving member 1340 maintains the second ozone water supply line 1300 at a constant temperature.

The ozone water may remove contaminants (for example, photoresist) that remain on the substrate W. The ozone water generated from the ozone water generator is supplied to the first ozone water supply line 1200 or the second ozone water supply line 1300. Hereinafter, the case of supplying the ozone water to the first ozone water supply line 1200 will be described as an example.

Ozone water is highly reactive and unstable, so it is difficult to supply the ozone water to the supply while maintaining the concentration of ozone water at the set concentration. In addition, filters typically cause a loss of pressure in the ozone water. The pressure loss causes a decrease in the solubility of the water, which acts as a solvent, to ozone gas. According to one exemplary embodiment of the present invention, ozone water passes through the first filter 1230. The ozone water passing through the first filter 1230 has a pressure loss. The pressure loss causes a decrease in the amount of dissolved ozone in the ozone water after passing through the first filter 1230. Therefore, it is difficult to supply ozone water with the constant amount of dissolved ozone. According to one exemplary embodiment of the present invention, the ozone water is sequentially passed through the first mixer 1210, the first cooler 1220, and the first filter 1230. The ozone water is cooled to a temperature below room temperature by the first cooler 1130. Since the solubility of ozone is inversely proportional to temperature, as the temperature of the ozone water is lower, solubility of the ozone water increases. When the ozone water is cooled to 15° C., the solubility of ozone is significantly higher than at room temperature (for example, 25° C.). Since the first filter 1230 is provided downstream of the first cooler 1220, the loss of the amount of dissolved ozone may be prevented even when the solubility of the ozone water is reduced by the first filter 1230. Furthermore, the loss of the amount of dissolved ozone may be prevented because the concentration of the ozone water cooled by the first heat reserving member 1320 may be kept constant. Therefore, ozone water may be supplied while maintaining a constant amount of dissolved ozone. Furthermore, the cleaning ability of the ozone water on the substrate W may be improved, allowing the substrate W to be treated efficiently.

Unlike when ozone water is supplied to the first ozone water supply line 1200, when ozone water is supplied to the second ozone water supply line 1300, the amount of ozone in the ozone water may be kept constant as described above. Only the type and concentration of the chemical solution changes depending on the type of contaminant remaining on the substrate W.

In the examples described above, the first cooler 1220 is illustrated as a constant temperature bath. Alternatively, however, the first cooler 1220 may be provided with a temperature adjusting member that regulates the temperature of the treatment solution to a set temperature.

In the example described above, the first mixer 1210 and the second mixer 1310 are described as inline mixers. Alternatively, however, the first mixer 1210 and/or the second mixer 1310 may include a tank and a circulation line, and the ozone water and pure water or ozone water and a chemical solution may be mixed by being fed into the tank and circulated along the circulation line.

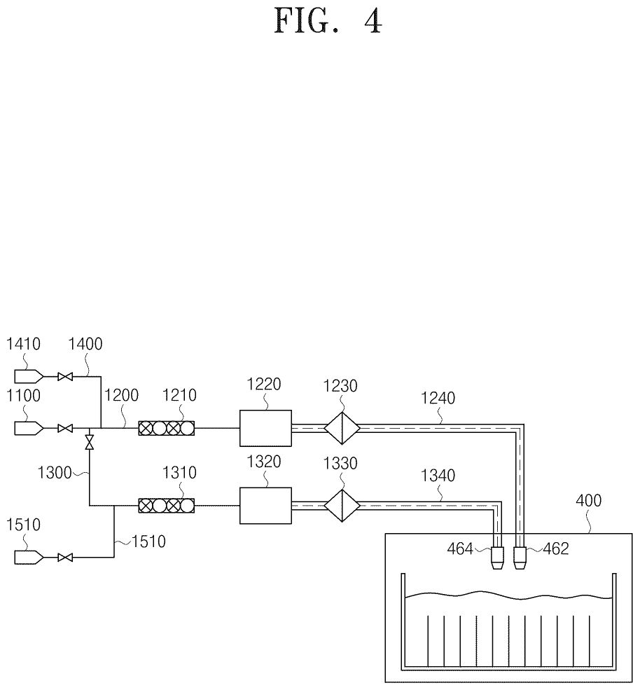

In the example described above, the liquid treating chamber 400 is illustrated as being a single wafer type treatment device. However, as shown in FIG. 4, the liquid treating chamber 400 may be provided in a batch type, and the substrate W may be treated by immersion in the treatment solution.

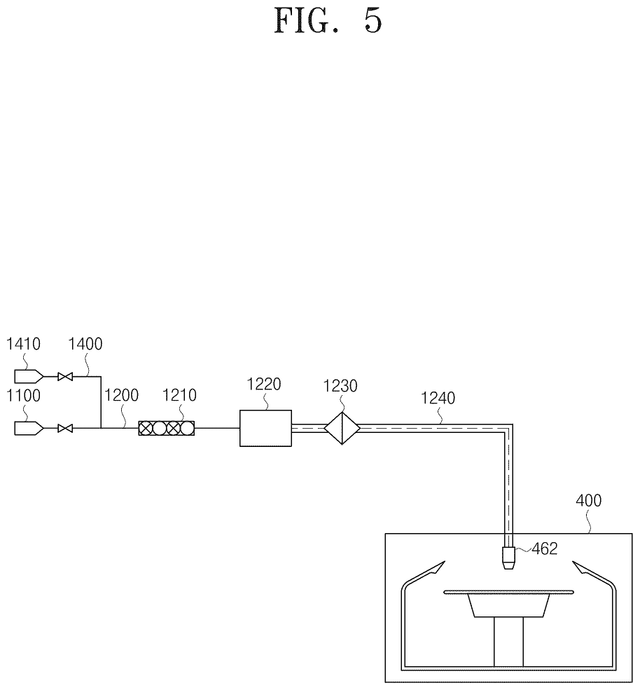

In the example described above, the present invention has been described based on the case where the first ozone water supply line 1200 and the second ozone water supply line 1300 are connected to the ozone water generator 1100 as an example. However, alternatively, only the first ozone water supply line 1200 or the second ozone water supply line 1300 may be connected, as shown in FIG. 5.

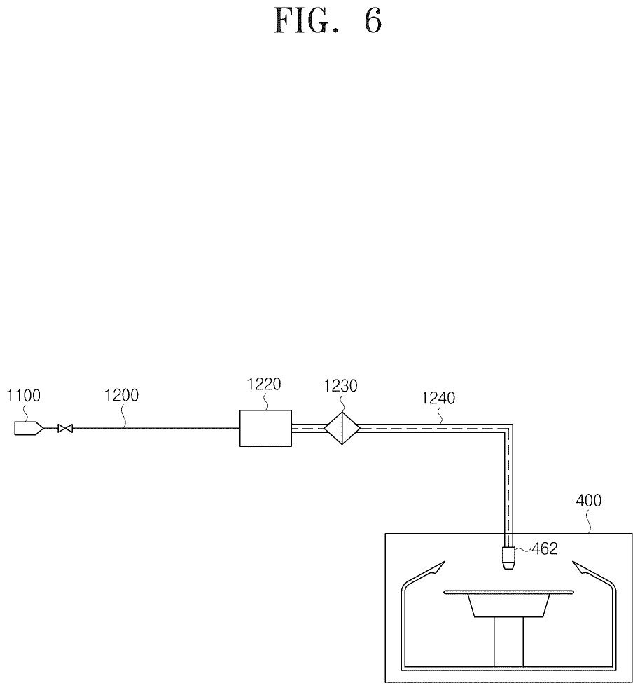

In the example described above, the present invention has been described based on the case where the pure water supply line 1400 is connected to the first ozone water supply line 1200, and the chemical solution supply line 1500 is connected to the second ozone water supply line 1300 as an example. Alternatively, however, as shown in FIG. 6, the pure supply line 1400 and the chemical solution supply line 1500 may not be provided, and the first mixer 1210 and the second mixer 1310 may not be provided.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

What is claimed is:

1. A substrate treating apparatus comprising:
a chamber for liquid-treating a substrate loaded into a treating space with a liquid containing ozone water; and
an ozone water supplying unit for supplying ozone water to the treating space,
wherein the ozone water supplying unit includes:
an ozone water generator for generating ozone water;
an ozone water supply line for supplying ozone water generated by the ozone water generator to the treating space; and
a cooler provided in the ozone water supply line to cool the ozone water flowing through the ozone water supply line.

2. The substrate treating apparatus of claim 1, wherein the cooler adjusts a temperature of the ozone water to a temperature lower than room temperature.

3. The substrate treating apparatus of claim 2, wherein the ozone water supplying unit further includes a filter installed in the ozone water supply line, and
the filter is installed downstream of the cooler.

4. The substrate treating apparatus of claim 3, wherein the filter is located adjacent to the cooler.

5. The substrate treating apparatus of claim 2, wherein the ozone water supplying unit further includes a heat reserving member for maintaining a temperature of the ozone water supply line to be constant, and
the heat reserving member is provided to be wrapped around the ozone water supply line downstream of the cooler.

6. The substrate treating apparatus of claim 4, further comprising:
a treatment solution supply source for storing a treatment solution;
a treatment solution supply line for supplying a treatment solution from the treatment solution supply source to the ozone water supply line; and
a mixer installed in the ozone water supply line to mix the ozone water with the treatment solution.

7. The substrate treating apparatus of claim 6, wherein the mixer is provided upstream of the cooler.

8. The substrate treating apparatus of claim 7, wherein the mixer includes an inline mixer.

9. The substrate treating apparatus of claim 6, wherein the treatment solution is deionized water.

10. The substrate treating apparatus of claim 6, wherein the treatment solution is a chemical solution.

11. The substrate treating apparatus of claim 10, wherein the chemical solution is hydrogen fluoride.

12. The substrate treating apparatus of claim 1, wherein the chamber includes:
a housing providing an inner space;
a cup for providing the treating space;
a support unit for supporting the substrate;
a nozzle for supplying ozone water to the substrate, and
the ozone water supply line is connected to the nozzle.

13. An ozone water supplying unit comprising:
an ozone water supply source;
an ozone water nozzle;
an ozone water supply line for connecting the ozone water supply source and the ozone water nozzle;
a cooler for cooling the ozone water; and
a filter,
wherein the cooler and the filter are disposed in the ozone water supply line.

14. The ozone water supplying unit of claim 13, wherein the filter is located adjacent to the chiller, but is located downstream of the cooler.

15. The ozone water supplying unit of claim 14, wherein the cooler cools the ozone water to a temperature lower than room temperature.

16. The ozone water supplying unit of claim 15, wherein the ozone water supplying unit further includes a heat reserving member, and
the heat reserving member is provided to be wrapped around the ozone water supply line downstream of the cooler.

17. The ozone water supplying unit of claim 15, further comprising:
a chemical solution supply source;
a chemical solution supply line; and
a mixer,
wherein the chemical solution supply source stores a chemical solution,
the chemical solution supply line supplies the chemical solution to the ozone water supply line,
the mixer mixes the chemical solution with the ozone water,
the mixer is installed downstream of a point where the chemical solution supply line is connected with the ozone water supply line connect, and
the chemical solution is deionized water or hydrogen fluoride.

18. A substrate treating apparatus comprising:
a chamber for liquid-treating a substrate loaded into a treating space with a treatment solution; and
an ozone water supplying unit for supplying a liquid containing ozone water to the treating space,
wherein the ozone water supplying unit includes:
an ozone water generator for generating ozone water;
a first ozone water supply line for connecting the ozone water generator with a first nozzle supplying the ozone water to the treating space;
a first cooler provided in the first ozone water supply line to cool the ozone water flowing through the first ozone water supply line;
a first heat reserving member provided to be wrapped around the first ozone water supply line downstream of the first cooler to maintain a temperature of the first ozone water supply line;
a pure water supply line for supplying pure water to the first ozone water supply line;
a pure water supply source for supplying the pure water to the pure water supply line;
a first mixer provided in the first ozone water supply line and located upstream of the first cooler, and mixing the pure water with the ozone water;
a second ozone water supply line connecting the ozone water generator with a second nozzle supplying the ozone water to the treating space;
a second cooler provided in the second ozone water supply line to cool the ozone water flowing through the second ozone water supply line;
a second heat reserving member provided to be wrapped around the second ozone water supply line downstream of the second cooler to maintain a temperature of the second ozone water supply line;
a chemical solution supply line for providing a chemical solution to the second ozone water supply line;
a chemical solution supply source for providing the chemical solution to the chemical solution supply line; and
a second mixer provided in the second ozone water supply line and located upstream of the second cooler, and mixing the chemical solution with the ozone water.

19. The substrate treating apparatus of claim 18, further comprising:
a first filter disposed adjacent to the first cooler downstream of the first cooler; and
a second filter disposed adjacent to the second cooler downstream of the first cooler.

20. The substrate treating apparatus of claim 19, wherein the chemical solution is a chemical solution that contains hydrogen fluoride.
